(19) United States
(12) Patent Application Publication
(10) Pub. No.: US 2010/0084583 A1
(43) Pub. Date: Apr. 8, 2010

(54) REDUCED IMPLANT VOLTAGE DURING ION IMPLANTATION

(76) Inventors: Christopher R. Hatem, Salisbury, MA (US); Ludovic Godet, North Reading, MA (US)

Correspondence Address: Nields, Lemack & Frame, LLC, 176 E. MAIN STREET, SUITE 5, WESTBOROUGH, MA, 01581, US

(21) Appl. No.: 12/245,938

(22) Filed: Oct. 6, 2008

(51) Int. Cl. H01J 37/08

(52) U.S. Cl. 250/492.21

(57) ABSTRACT

A method for ion implantation is disclosed which includes decreasing the implant energy level as the implant process is ongoing. In this way, either a box-like profile or a profile with higher retained dose can be achieved, enabling enhanced activation at the same junction depth. In one embodiment, the initial implant energy is used to implant about 25% of the dose. The implant energy level is then reduced and an additional 50% of the dose is implanted. The implant energy is subsequently decreased again and the remainder of the dose is implanted. The initial portion of the dose can optionally be performed at cold, such as cryogenic temperatures, to maximize amorphization of the substrate.

### BACKGROUND OF THE INVENTION

Ion implanters are commonly used in the production of semiconductor wafers. An ion source is used to create an ion beam, which is then directed toward the wafer. As the ions strike the wafer, they dope a particular region of the wafer. The configuration of doped regions defines their functionality, and through the use of conductive interconnects, these wafers can be transformed into complex circuits.

A block diagram of a representative ion implanter 100 is shown in FIG. 1. An ion source 110 generates ions of a desired species. In some embodiments, these species are atomic ions, which may be best suited for high implant energies. In other embodiments, these species are molecular ions, which may be better suited for low implant energies. These ions are formed into a beam, which then passes through a source filter 120. The source filter is preferably located near the ion source. The ions within the beam are accelerated/decelerated in column 130 to the desired energy level. A mass analyzer magnet 140, having an aperture 145, is used to remove unwanted components from the ion beam, resulting in an ion beam 150 having the desired energy and mass characteristics passing through resolving aperture 145.

In certain embodiments, the ion beam 150 is a spot beam. In this scenario, the ion beam passes through a scanner 160, which can be either an electrostatic or magnetic scanner, which deflects the ion beam 150 to produce a scanned beam 155-157. In certain embodiments, the scanner 160 comprises separated scan plates in communication with a scan generator. The scan generator creates a scan voltage waveform, such as a sine, sawtooth or triangle waveform having amplitude and frequency components, which is applied to the scan plates. In a preferred embodiment, the scanning waveform is typically very close to being a triangle wave (constant slope), so as to leave the scanned beam at every position for nearly the same amount of time. Deviations from the triangle are used to make the beam uniform. The resultant electric field causes the ion beam to diverge as shown in FIG. 1.

In an alternate embodiment, the ion beam 150 is a ribbon beam. In such an embodiment, there is no need for a scanner, so the ribbon beam is already properly shaped.

An angle corrector 170 is adapted to deflect the divergent ion beamlets 155-157 into a set of beamlets having substantially parallel trajectories. Preferably, the angle corrector 170 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil. Alternatively, other structures, such as parallelizing lenses, can also be utilized to perform this function.

Following the angle corrector 170, the scanned beam is targeted toward the workpiece 175. The workpiece is attached to a workpiece support. The workpiece support provides a variety of degrees of movement.

The workpiece support is used to both hold the wafer in position, and to orient the wafer so as to be properly implanted by the ion beam. To effectively hold the wafer in place, most workpiece supports typically use a circular surface on which the workpiece rests, known as a platen. Often, the platen uses electrostatic force to hold the workpiece in position. By creating a strong electrostatic force on the platen, also known as the electrostatic chuck, the workpiece or wafer can be held in place without any mechanical fastening devices. This minimizes contamination and also improves cycle time, since the wafer does not need to be unfastened after it has been implanted. These chucks typically use one of two types of force to hold the wafer in place: coulombic or Johnson-Rahbeck force.

The workpiece support typically is capable of moving the workpiece in one or more directions. For example, in ion implantation, the ion beam is typically a scanned or ribbon beam, having a width much greater than its height. Assume that the width of the beam is defined as the x axis, the height of the beam is defined as the y axis, and the path of travel of the beam is defined as the z axis. The width of the beam is typically wider than the workpiece, such that the workpiece does not have to be moved in the x direction. However, it is common to move the workpiece along the y axis to expose the entire workpiece to the beam.

Ion implantation is an effective method to introduce dopants into a substrate, however there are unwanted side effects that must be tackled. For example, implanted ions often distribute themselves at deeper depths than expected. It is believed that this is caused by a phenomenon known as channeling, where ions are moved or channeled along axes and planes of symmetry in the crystalline structure. This channeling effect causes a deeper concentration of the dopant, which increases the effective junction depth. FIG. 2 shows a representative graph of ion concentration versus substrate depth. Line 100 represents the ideal profile, including tail 120. Note that due to channel effects, the actual concentration has a large tail 110, which represent an increased junction depth.

Traditionally, to overcome this problem, the workpiece or substrate is implanted with heavier species before the actual dopant implantation. This implantation is known as the pre-amorphous implantation, or PAI. Typically, a heavier species, such as silicon or germanium is implanted into the substrate to effectively change the silicon crystalline structure into an amorphous layer. This amorphous layer significantly reduces channeling, thereby alleviating the issue described above.

However, the PAI step is not without its drawbacks. These species tend to cause residual damage at end of range (referred to as EOR defects). For example, germanium creates a large amount of damage, in terms of dislocation. Furthermore, germanium does not recrystallize well during the annealing process. These EOR defects introduce leakage into the resulting CMOS transistors. As junction depths get smaller and smaller, this leakage becomes more problematic.

Therefore, there exists a need for an ion implantation method that is capable of creating ultra-shallow junctions, without the issues and drawbacks described above.

### SUMMARY OF THE INVENTION

The problems of the prior art are overcome by the ion implantation method described in the present disclosure. The disclosure provides a method for ion implantation that includes decreasing the implant energy level as the implant process is ongoing. In this way, either a box-like profile or a profile with higher retained dose can be achieved, enabling enhanced activation at the same junction depth. In one embodiment, the initial implant energy is used to implant about 25% of the dose. The implant energy level is then reduced and an additional 50% of the dose is implanted. The implant energy is subsequently decreased again and the remainder of the dose is implanted. The initial portion of the dose can optionally be performed at cold, such as cryogenic temperatures, to maximize amorphization of the substrate.

### BRIEF DESCRIPTION OF FIGURES

FIG. 1 represents a traditional ion implanter;

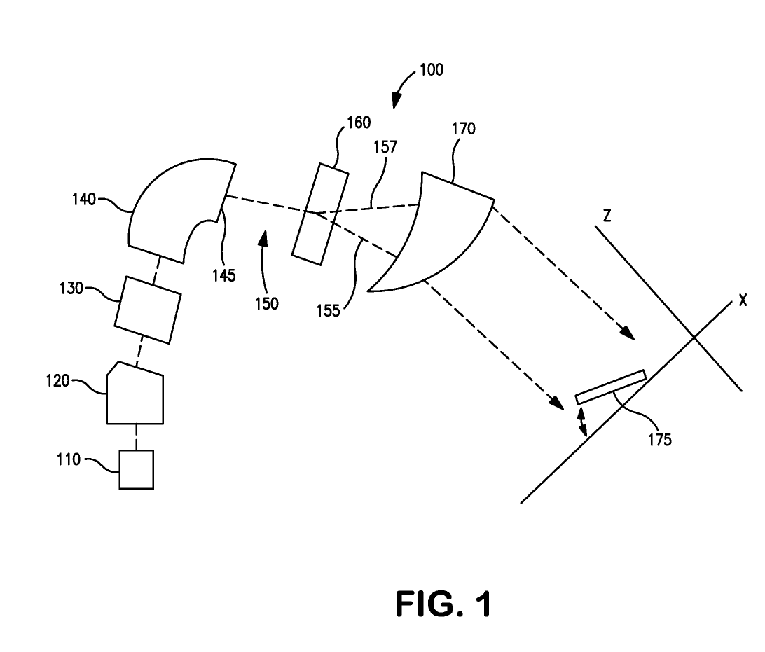

FIG. 2 represents a graph showing ion concentrations after a traditional ion implant;

FIG. 3 represents a graph showing ion concentrations after an ion implantation according to the present disclosure;

FIG. 4 represents a process flow diagram of an ion implantation according to one embodiment;

FIG. 5 illustrates the relationship between implant energy level and total dosage according to one embodiment;

FIG. 6 illustrates the relationship between implant energy level and total dosage according to a second embodiment;

FIG. 7 illustrates the relationship between implant energy level and total dosage according to a third embodiment; and

FIG. 8 illustrates the relationship between implant energy level and total dosage according to a fourth embodiment.

### DETAILED DESCRIPTION OF THE INVENTION

As stated above, the creation of ultra shallow junctions can be problematic. The use of PAI causes EOR defects and subsequent leakage in the CMOS transistor. The removal of PAI reintroduces the channeling phenomenon that PAI was integrated into the implant process to prevent.

In many cases, the desired dopant is boron. Previously, when junction depths were greater, atomic ions (B+) were implanted. However, to create more shallow implants, either the implant energy must be reduced, or the mass-to-charge ratio must be increased. A significant reduction in implant energy tends to increase space charge effects in the ion beam. Therefore, it is preferably to increase the mass-to-charge ratio to achieve shallow implant depths. This ratio is increased by substituting atomic boron with a molecular ion containing boron. For example, to create the required shallow depth junctions, molecular ions containing boron, such as BF₂, carborane (C₂B₁₀H₁₂), diborane (B₂H₆), and octadecaborane (B₁₈H₂₂) are typically used. Other molecular ions used for N-type doping also include As₂, As₄ and P₂. Other ions typically used also include carbon and germanium.

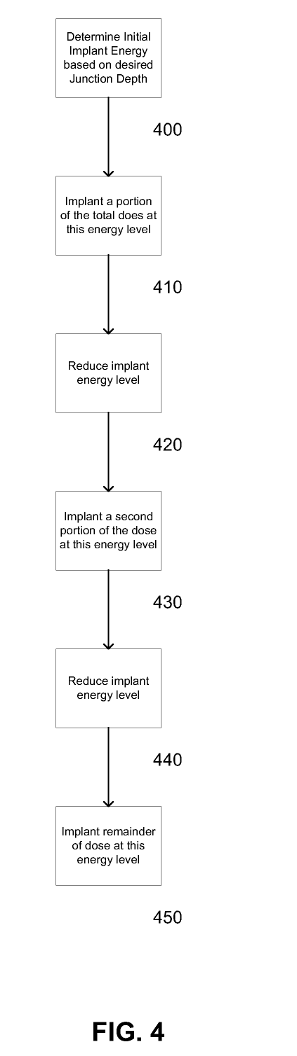

One approach to eliminating the EOR defects, without re-introducing channeling effects, is through variation in the implant energy. FIG. 4 shows a representation process flow diagram for one embodiment. In the preferred embodiment, an initial implant energy is selected based on the desired junction depth, as shown in Step 400. A portion of the dose is implanted at this energy level. In one embodiment, 25% of the dose is done at this energy level, as shown in Step 410. In another embodiment, a smaller dose, such as 15%, is performed at this level. In another embodiment, a greater dose, such as 50%, is performed at the high energy level. The ramp voltage can be completed in a single linear progression or in a step-wise fashion at a specific ramp rate.

After this portion is implanted, the implant energy is lowered, such as to 60% of the initial energy level, as shown in Step 420. In other embodiments, this energy level is between 40% and 75% of the initial energy level. At this lower level, a portion of the total dose, such as between 25%-75%, preferably about 50% of the dose, is implanted, as shown in Step 430. Finally, at a third energy level, lower than either the initial or second implant energy level, such as about 25% of the initial energy level, is used to complete the dose, as shown in Step 450.

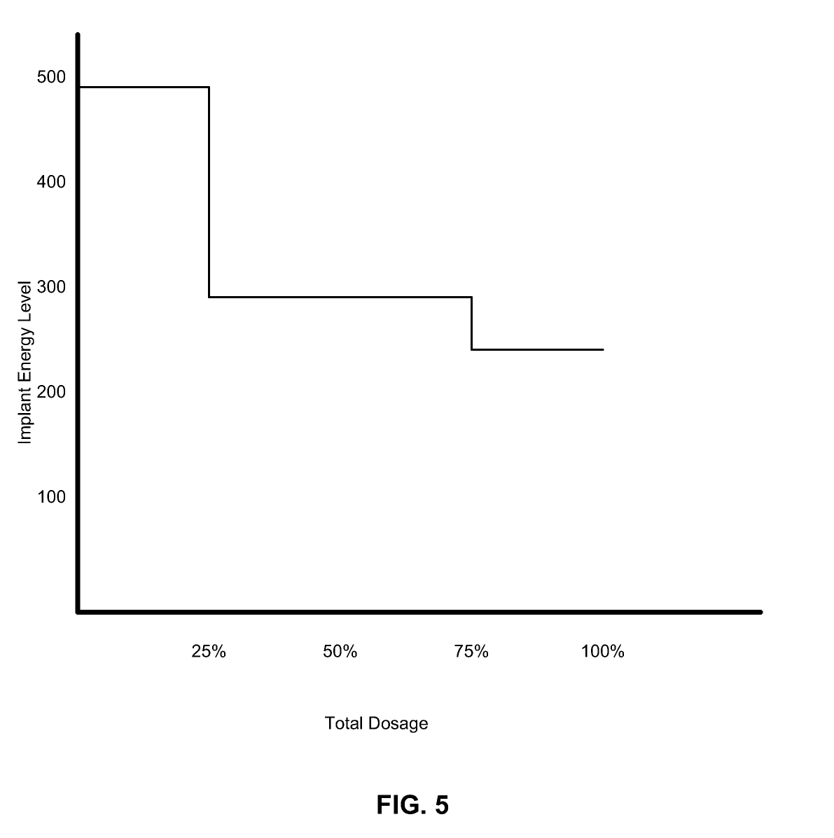

In one particular embodiment, shown in FIG. 5, a relatively high energy implant of 500 eV is used initially. The preferred dopant is carborane (C₂B₁₀H₁₂). Approximately 25% of the implant dose is completed at this initial energy level.

The implant energy is then reduced to 300 eV and 50% of the desired dose is implanted. The implant energy is reduced again to about 250 eV and the implant is completed.

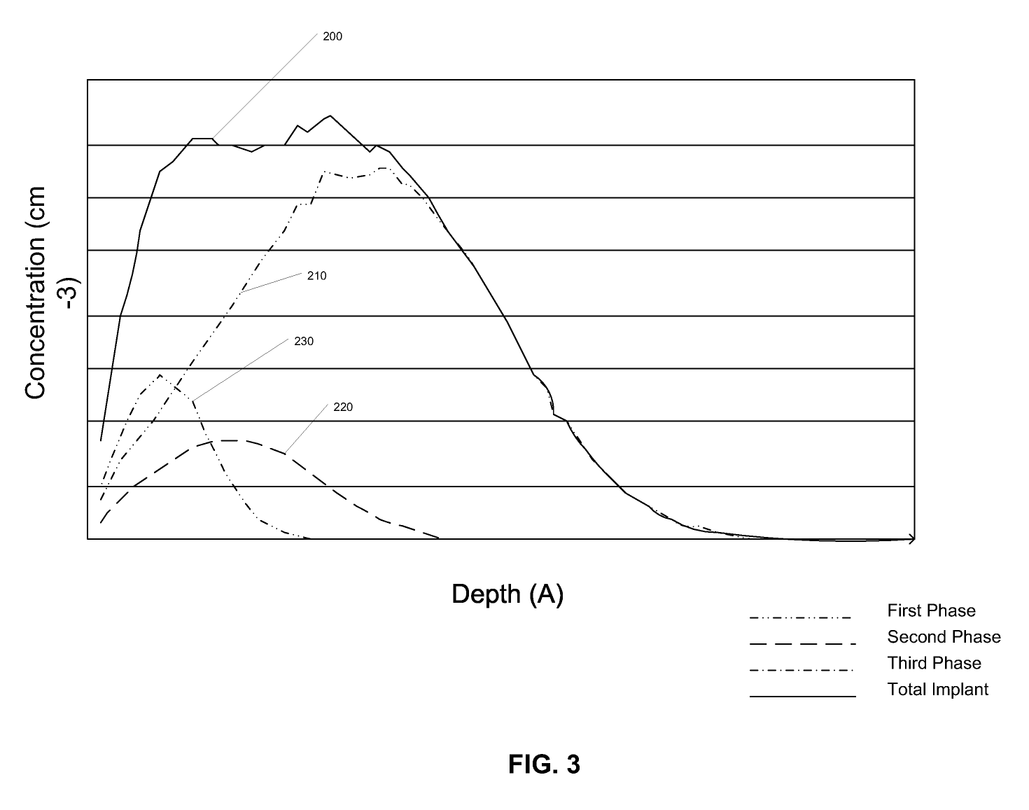

FIG. 3 shows a representative graph showing the effects of each of the three implants described above, as well as the aggregate result 200. The first implantation is done at high energy and yields a profile 210. This first implantation serves to establish the junction depth, as the subsequent implants are performed at lower energy levels and therefore at more shallow depths. The second implant profile 220 increases the ion concentration at the midrange of the substrate. Note that few ions reach the junction depth, thereby minimizing additional channeling. The third implant profile 230 increases the ion concentration near the surface of the substrate. Again, this implant does not affect the junction depth, as few ions penetrate to this level. The sum of these three implants is shown as the aggregate concentration 200. This sequence of implants creates a box-shaped concentration profile, rather than the typical bell-shaped profiles. This represents an improvement in ion uniformity throughout the substrate.

While the above example uses three discrete energy levels, other embodiments are within the scope of the disclosure. For example, in one embodiment, more than three energy levels are used. In another embodiment, only two energy levels are used.

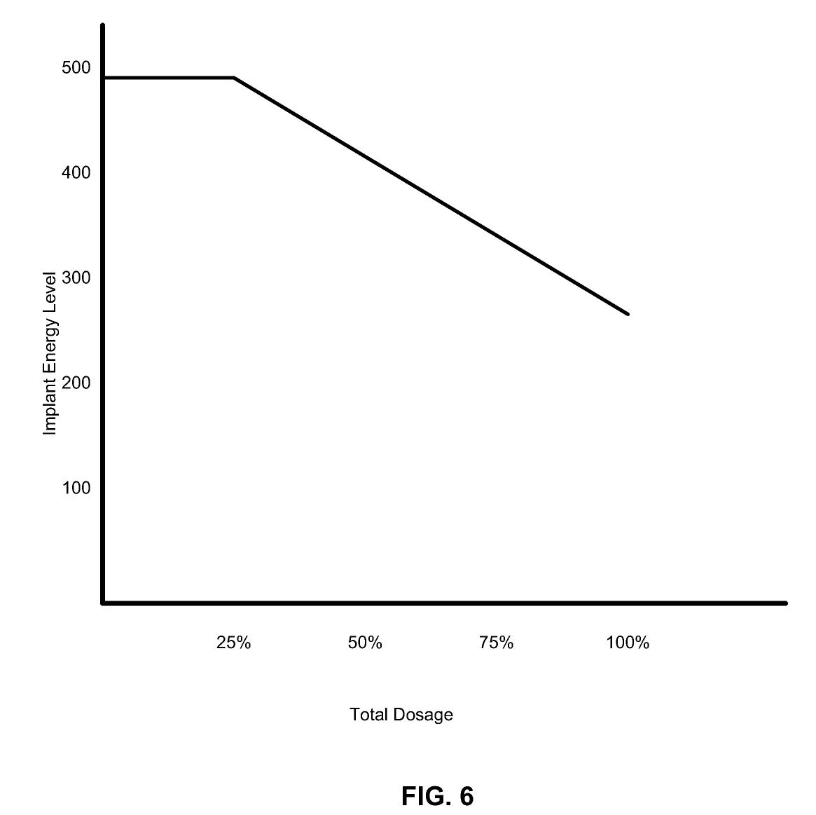

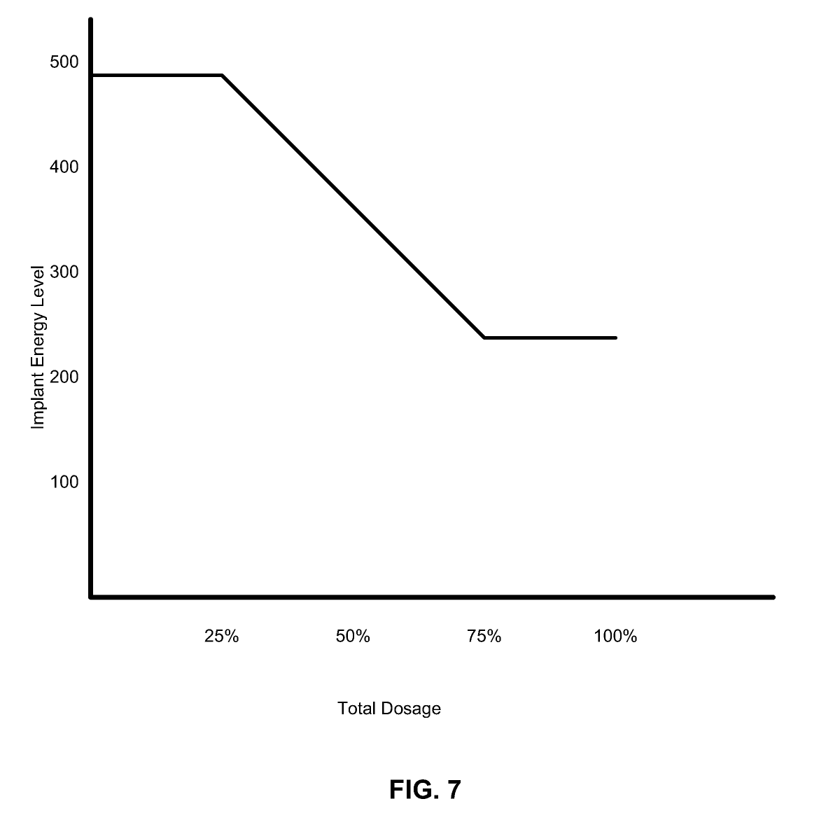

Additionally, while FIG. 5 shows discrete energy levels, these are not required. For example, the initial implant may be performed at an initial energy level, such as 500 eV. The remainder of the implant may be performed using a decreasing implant energy level. In one embodiment, the implant energy linearly decreases from its initial level to its final energy level, as shown in FIG. 6. In another embodiment, shown in FIG. 7, the implant energy begins at its initial level. After a portion of the dose has been implanted, the level decreases, such as linearly, to a second implant level. The remainder of the dose is then implanted at this second level.

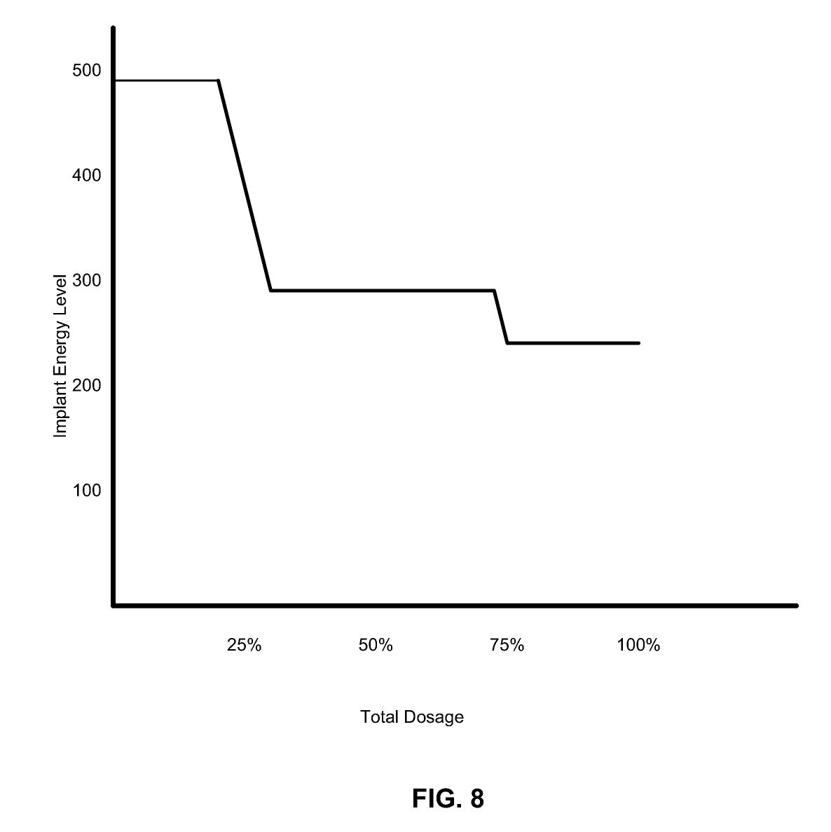

In another embodiment, shown in FIG. 8, more than two implant energy levels are utilized. As before, the implant energy begins at its initial level. After a portion of the dose has been implanted, the level decreases, such as linearly, to a second implant level, where it remains for a second portion of the dose. After this portion has been implanted, the energy level decreases again, to a third implant level, where the remainder of the dose is implanted. An example of this energy profile is shown in FIG. 8. The slopes of the ramps between energy levels used in FIG. 8 are uniform. However, this is not required. The transition from the initial implant energy level to the intermediate level can be more or less rapid than the subsequent transitions. In addition, the transitions need not be linear in nature. Other functions, such as exponential, are also within the scope of the disclosure. Furthermore, while embodiments showing two or three energy levels have been described, the disclosure is not limited to these embodiments. Any number of implant energy levels may be utilized.

The implant energy level can follow any profile, as long as the energy level at a later point in time is never greater than any implant energy level used earlier.

In another embodiment, rather than modifying the implant energy level, the mass of the molecular ion is varied. To achieve the greatest depths, a light molecular ion is used initially. After a portion of the dosage has been implanted, a second, heavier molecular ion is used. The increased mass will insure that the ion will not penetrate as deeply as the initial dosage. This process can then be repeated using a yet heavier ion if desired.

This method of reducing the implant energy during the implant process can be used in conjunction with variations in implant temperature. For example, in one embodiment, the initial implant is performed at cold, such as cryogenic, temperatures, so as to maximize the amorphization of the substrate. Such temperatures are preferably less than 0C, and typically between 0° C. and −100° C. In another embodiment, the entire implant process is performed at cryogenic temperatures.

The above implant method requires minimal changes to existing ion implantation equipment. This technique results in higher activation with reduced junction depths. Furthermore, the decreasing implant energy will enable higher implanted dose and lower resistances without an increase in the junction depth.

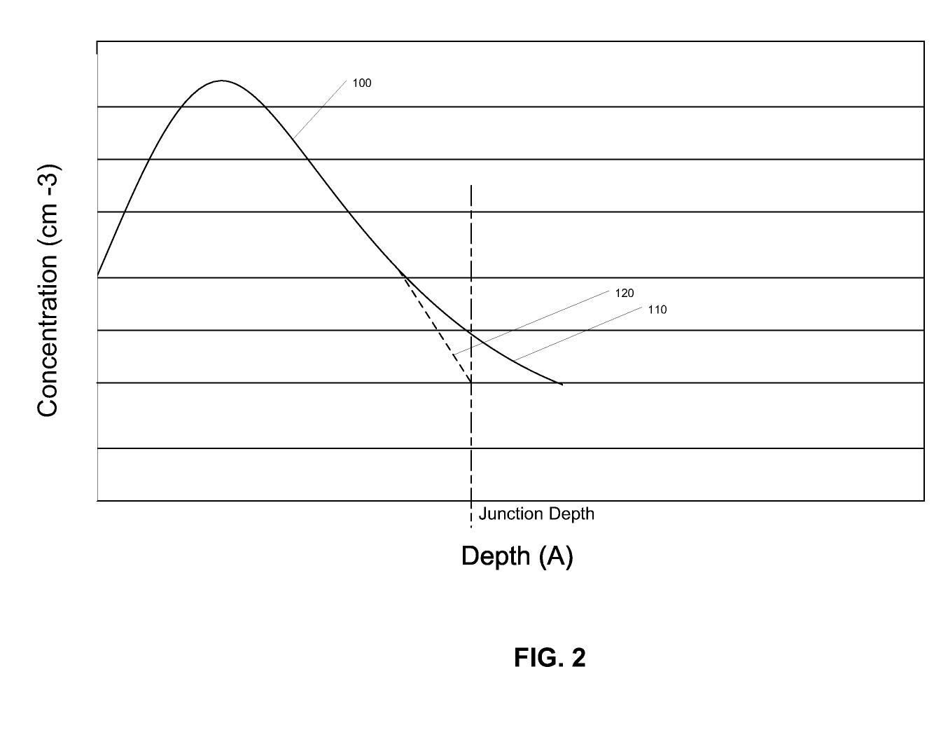

FIG. 3 shows the ion concentration as a function of depth. Note that, when compared to the typical concentration (as seen in FIG. 2), this graph has a more box-like shape. Since the area under this curve represents the total number of implanted ions, a box-like shape corresponds to an increased implanted dose. Thus, higher activation can be achieved within any desired junction depth. While this technique is well suited to creating improved ultra-shallow junctions, it is equally suited to creating more traditional depth junctions. In such situations, higher implant energies would be employed.

What is claimed is:

1. A method of implanting ions into a substrate, comprising:
a. Selecting an initial implant energy level;
b. Implanting a portion of the desired dose at said initial implant energy level;
c. Decreasing said implant energy level to a second level; and
d. Implanting a second portion of said desired dose at said second level.

2. The method of claim 1, further comprising:
a. decreasing said implant energy level to a level lower than the previous implant energy level; and
b. implanting a portion of said desired dose at said lower level.

3. The method of claim 2, further comprising repeating said decreasing and implanting steps.

4. The method of claim 1, wherein said first portion comprises about 25% of said desired dose.

5. The method of claim 1, wherein said second portion comprises about 50% of said desired dose.

6. The method of claim 1, wherein said decrease from said initial implant level to said second level is linear.

7. The method of claim 1, wherein said decrease from said initial implant level to said second level is a step function.

8. The method of claim 1, wherein said second level is between 50% and 75% of said initial energy level.

9. The method of claim 1, wherein said first portion of said implant is performed at cold temperature.

10. The method of claim 1, wherein said method is performed at cold temperature.

11. The method of claim 1, wherein said ions are selected from the group consisting of BF2, germanium, carbon, carborane (C₂B₁₀H₁₂), diborane (B₂H₆), octadecaborane (B₁₈H₂₂), As₂, As₄ and P₂.
